(19) United States
(12) Patent Application Publication
(10) Pub. No.: US 2025/0148182 A1
(43) Pub. Date: May 8, 2025

(54) SPATIALLY AWARE LOW POWER TECHNIQUES FOR DESIGN FOR TESTABILITY

(71) Applicant: Micron Technology, Inc., Boise, ID (US)

(72) Inventors: Mahesh Rawal, Hyderabad (IN); Banadappa Shivaray, Gulbarga (IN); Shrikrishna Pundoor, Bangalore (IN); Kantharaj Shamenahalli Eswarappa, Bangalore (IN)

(21) Appl. No.: 18/914,937

(22) Filed: Oct. 14, 2024

Related U.S. Application Data
(60) Provisional application No. 63/595,589, filed on Nov. 2, 2023.

(51) Int. Cl. G06F 30/333; G06F 30/392

(52) U.S. Cl. CPC G06F 30/333; G06F 30/392

(57) ABSTRACT

The subject application relates to spatially aware Design for Testability (DFT). For instance, a method may include dividing a layout of a circuit under test (CUT) into a plurality of grids based on a preconfigured policy, creating, based on the preconfigured policy, a plurality of targeted portions from the divided layout of the CUT, applying a DFT test pattern to the plurality of targeted portions; and capturing data output from the plurality of targeted portions.

### PRIORITY INFORMATION

This Application claims the benefit of U.S. Provisional Application No. 63/595,589, filed on Nov. 2, 2023, the contents of which are incorporated herein by reference.

### TECHNICAL FIELD

The present disclosure relates generally to spatially aware design for testability (DFT) and particularly, to use of spatially aware Automatic Test Pattern Generation (ATPG), Logic Built-In-Self-Test (LBIST), Memory Built-In-Self-Test (MBIST), and/or Embedded Deterministic Test (EDT) test patterns for integrated circuit testing.

### BACKGROUND

Testing integrated circuits may involve several steps, which can vary depending upon the complexity of the circuit and/or specific testing requirements. Generally, the specifications and specific testing requirements for the integrated circuit testing process may be predefined before fabrication.

### BRIEF DESCRIPTION OF THE DRAWINGS

FIG. 1 is a block diagram of an example spatially aware DFT process including an application of DFT test patterns (also called ATPG/LBIST/MBIST/EDT test patterns) at post-physical design (post-PD) stage in accordance with a number of embodiments of the present disclosure.

FIG. 2 is a block diagram of a spatial aware DFT-Gate Level Simulation (DFT-GLS) post-PD scan and a circuit under test (CUT) in accordance with a number of embodiments of the present disclosure.

FIG. 3 is a block diagram for dividing a physical layout of the CUT using a cell density method and creating targeted portions from the divided layout for a selective application of the DFT test patterns in accordance with a number of embodiments of the present disclosure.

FIG. 4 is a block diagram for dividing the physical layout of the CUT using a fixed grid method and creating the targeted portions from the divided layout for the selective application of the DFT test patterns in accordance with a number of embodiments of the present disclosure.

FIG. 5 is a block diagram for dividing a physical layout of the CUT using an IR voltage drop method and creating the targeted portions for the selective application of the DFT test patterns in accordance with a number of embodiments of the present disclosure.

FIG. 6 is a block diagram of data path gating in one of the targeted portions in accordance with a number of embodiments of the present disclosure.

FIG. 7 is an example block diagram of the CUT that implements the spatial aware DFT-GLS post-PD scan in accordance with a number of embodiments of the present disclosure.

FIG. 8 is a flow diagram of a method for implementing targeted spatial aware DFT in accordance with a number of embodiments of the present disclosure.

FIG. 9 illustrates an example computer system within which a set of instructions, for causing the machine to perform various methodologies discussed herein, can be executed.

### DETAILED DESCRIPTION

The present disclosure includes apparatuses and methods related to spatially aware DFT techniques. The spatially aware DFT techniques may include an application of DFT test patterns to targeted portions of a circuit under test (CUT). DFT test patterns may include ATPG, EDT, LBIST and/or MBIST test patterns. The targeted portions of the CUT may include a grouping of grids or divided physical layout of the CUT based on a preconfigured policy. In some embodiments, the preconfigured policy may define a process of implementing the spatially aware DFT techniques such as, without limitation, dividing of physical layout of the CUT, creating the targeted portions from the divided layout, associating a clock signal to each of the targeted portions, and implementing a data path gating on flops of the targeted portions. In these embodiments, an individual or sequential testing of the targeted portions using their corresponding clock signals may avoid simultaneous toggling of physically proximate high-speed circuits and close a gap between an assessed yield versus real yield while generating DFT test patterns with minimal to no impact to test time.

Assessed yield is an estimate of the yield based on design and process parameters. Assessed yield may be calculated before the actual manufacturing process. On the other hand, real yield may refer to the yield obtained after the completion of the manufacturing process. Real yield may represent percentage of chips that meet the required functionality and quality standards out of the total number of chips manufactured.

In some embodiments, the preconfigured policy may include user-entered instructions for creating the targeted portions. The user-entered instructions may include conditions and/or thresholds to form the targeted portions. For example, a user-entered instruction may include the use of a fixed grid method to initially divide a physical layout of the CUT into 16 different portions (or grids). A user-entered threshold number of portions may then be used as an additional condition to create the targeted portions. For example, the threshold number of portions for each of the targeted portions may include a maximum of 4 adjacent portions. In this example, the targeted portions may correspond to 4 groups where each group (or targeted portion) comprises of 4 adjacent portions. In other embodiments, the preconfigured policy may utilize different other conditions, thresholds, or classifications for creating the targeted portions. For example, the targeted portions may be created based on cell density, associated IR voltage drops, or any other user-entered conditions such as particular locations of the grid on the CUT.

In some embodiments, the preconfigured policy may further include user-entered instruction for associating a clock signal to each of the targeted portions. In these embodiments, the preconfigured policy may define the sequence of testing the targeted portions and use of the corresponding clock signals for toggling of the targeted portions for testing. For example, the CUT is divided into 4 targeted portions and each targeted portion is associated with a corresponding clock signal. In this example, the individual clock signals associated with the corresponding targeted portions may facilitate individual, parallel, sequential, or simultaneous application of the DFT test patterns to the targeted portions. In some embodiments, the preconfigured policy may further include user-entered instruction for data path gating of flops on each of the targeted portions to reduce capture power of data output during a test mode.

The spatial aware DFT techniques may include techniques such as use of ATPG, EDT, LBIST and MBIST test patterns to enhance testability of integrated circuits. For techniques such as the use of ATPG test patterns, the ATPG works by simulating, for example, behavior of the targeted portions under different input patterns to identify the inputs that can cause the targeted portions to show faulty behavior. The faulty behavior can be stuck-at fault behavior, transition fault behavior, and the like. After simulation, the ATPG test patterns can then be used to verify the functionality of the targeted portions of the CUT. In some embodiments, the preconfigured policy may define the clock gating and data path gating of flops in each of the targeted portions. By applying the ATPG test patterns on the targeted portions and utilizing the clock gating and/or data path gating during testing, the application of the ATPG test patterns may avoid simultaneous toggling of physically proximate high-speed circuits. The high-speed circuits may include components that may operate at high clock frequencies.

As described herein, clock gating may include selective enabling of corresponding clock signals of the targeted portions. Data path gating may include connecting a Low Power Enable (LPE) signal, for example, to a gating logic of each flop in the targeted portions to enable or disable flow of data to specific paths. The preconfigured policy may user-entered instruction that define the timing, conditions, sequence, or parameters associated with the clock gating and the data path gating.

For techniques such as the use of LBIST and/or MBIST test patterns, the preconfigured policy may similarly define the implementation of the clock gating and the data path gating of flops on each of the targeted portions. LBIST and MBIST test patterns may include built-in test patterns to evaluate functionality of logic circuitry and memory cells, respectively, of the CUT. By applying the LBIST/MBIST test patterns on the targeted portions and utilizing the clock gating and/or data path gating during testing, the application of the LBIST/MBIST test patterns may similarly avoid simultaneous toggling of physically proximate high-speed circuits and thereby reduces power during capture of data output.

As used herein, the singular forms “a”, “an”, and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

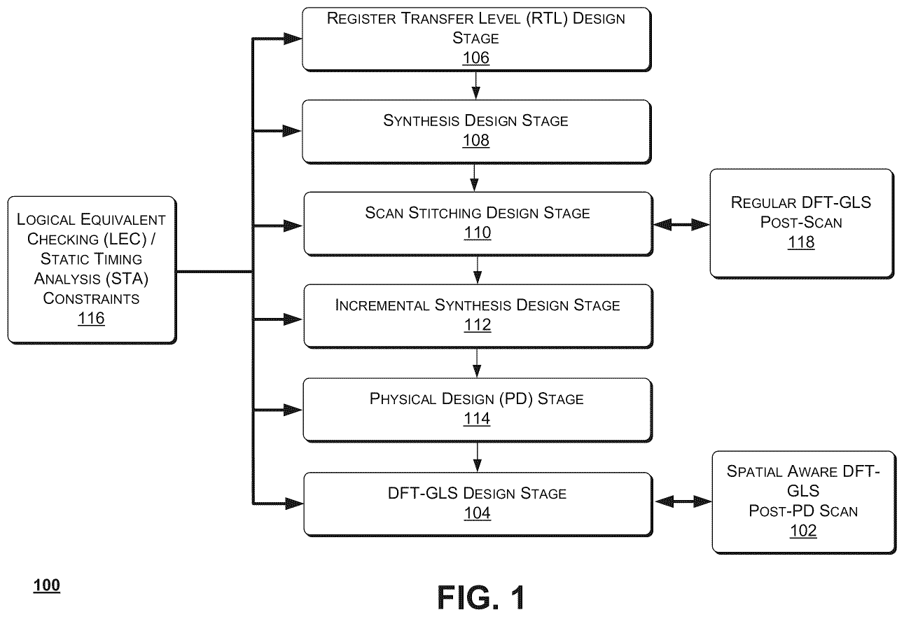

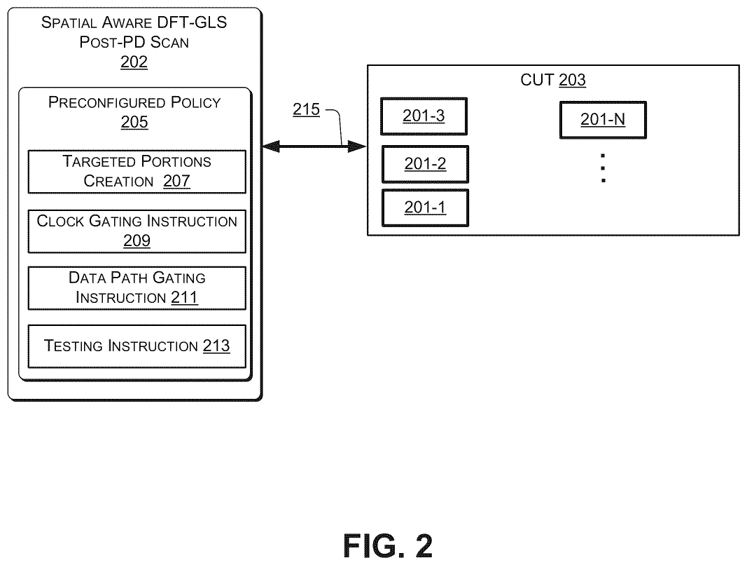

The figures herein follow a numbering convention in which the first digit or digits correspond to the drawing figure number and the remaining digits identify an element or component in the drawing. Similar elements or components between different figures may be identified by the use of similar digits. For example, 102 may reference element “02” in FIG. 1, and similar element may be referenced as 202 in FIG. 2. Further, analogous elements within a Figure may be referenced with a hyphen and extra numeral or letter. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

FIG. 1 is a block diagram of an example spatially aware DFT process 100 including an application of DFT test patterns at post-PD stage in accordance with a number of embodiments of the present disclosure. The application of the DFT test patterns (not shown) may correspond to an application of the ATPG test pattern, LBIST test pattern, MBIST test pattern, EDT test pattern, or a combination thereof, to circuit components or CUT. The example DFT process 100 may be employed to ensure functional correctness, quality, and reliability of manufactured circuits. At a high level, the DFT process 100 may include an application of the DFT test patterns from a spatial aware DFT-GLS post-PD scan 102 to the circuit components at a DFT-GLS design stage 104. The DFT test patterns may be individually, in parallel, or sequentially applied to targeted portions of the CUT to avoid the simultaneous toggling of physically proximate high-speed circuits and close a gap between an assessed yield versus real yield.

As shown in FIG. 1, the DFT process 100 may include, without limitation, a register transfer level (RTL) design stage 106, synthesis design stage 108, scan stitching design stage 110, incremental synthesis design stage 112, and physical design (PD) stage 114. The DFT process 100 further shows a logical equivalent checking and/or static mining analysis (LEC/STA) constraints 116 that may be applied to the RTL design stage 106, synthesis design stage 108, scan stitching design stage 110, incremental synthesis design stage 112, PD stage 114, and/or the DFT-GLS design stage 104. Further, a regular DFT-GLS post-scan 118 may be applied to a circuit at the scan stitching design stage 110. As described herein, the regular DFT-GLS post-scan 118 may include the application of the DFT test patterns without regard to the location of the components such as logic circuitry and/or memory cells on the CUT. In contrast, the spatial aware DFT-GLS post-PD scan 102 may apply the DFT test patterns to the targeted portions on the CUT.

RTL design stage 106 is a stage in the DFT process 100 that can involve modelling of a digital circuit using a high-level language or description that specifies the behavior of the digital circuit in terms of registers, data paths, and control logic. A generated digital circuit model may then be used as input to the synthesis design stage 108. For example, a simple 2-bit adder circuit may receive input bits from two input wires, use a combination logic to perform an addition operation, and store a sum in a register that can be connected to an output wire. In this example, the RTL design stage 106 may represent the behavior of the 2-bit adder circuit at the register level. The RTL design stage 106 may describe how data is transferred between registers and how operations are performed using the combinational logic.

Synthesis design stage 108 is a stage in the DFT process 100 where an RTL model from the RTL design stage 106 is converted into a gate-level netlist. Here, the RTL model is an early representation of the circuit and is subject to further refinement at least during the synthesis design stage 108. The gate-level netlist may include detailed representation of the digital circuit in terms of logic gates, flip-flops, and the like. The synthesis design stage 108 may involve optimizing the gate-level netlist for factors such as power consumption, area, and timing constraints, while maintaining the functionality specified by the digital circuit model from the RTL design stage 106. Once the gate-level netlist is generated at the synthesis design stage 108, the gate-level netlist may be used for further analysis and testing. For example, the MBIST test patterns (not shown) from the regular DFT-GLS post-scan 118 may be applied after the generation of the gate-level netlist at the synthesis design stage 108.

Scan stitching design stage 110 is a stage in the DFT process 100 where scan chains are inserted into the gate-level netlist that were generated by the synthesis design stage 108. Here, the scan chains may facilitate the DFT testing by providing a way to load and unload DFT test patterns into the circuit. The scan chains may be inserted into the circuit, for example, by stitching them into the design at the end of the synthesis design stage 108. During the scan stitching design stage 110, the flip-flops in the circuit may be grouped together into a scan chain. The flip-flops are then reconnected in a specific order to form the scan chain. In some embodiments, a corresponding control logic (not shown) may be generated to enable the scan chains during testing mode. At the testing mode, the regular DFT-GLS post-scan 118 may use the gate-level netlist to simulate, for example, the behavior of the circuit and after simulation, the DFT test patterns from the regular DFT-GLS post-scan 118 may then be applied to identify faults that may occur during operation of the circuit.

Incremental synthesis design stage 112 is a stage in the DFT process 100 where the synthesis is performed on a smaller portion of the design rather than the entire design. For example, the original design may be analyzed and portions of the design that have been changed or modified are identified. In this example, the incremental synthesis design stage 112 may implement the performing of the synthesis on the modified portions only, resulting in faster synthesis times. The incremental synthesis design stage 112 may typically be implemented when there is a need to make small changes to the original design rather than approaching the small changes by going again through the entire synthesis process.

Physical design (PD) stage 114 is a stage in the DFT process 100 where the circuit design is translated into a physical layout, which can be fabricated in silicon. The PD stage 114 may include floor planning, placement, and routing of the various components. The PD stage 114 may ensure that the logic circuitry may function as intended or designed, and that the circuit meets performance, power, and area requirements.

LEC/STA constraints 116 may include a step in the DFT process 100 to ensure that the design is functionally correct, meets the timing requirements, and can be reliably tested. For example, the LEC constraints may be used to check if the RTL model from the output of the RTL design stage 106 and the gate-level netlist are functionally equivalent. In this example, the LEC constraints from the LEC/STA constraints 116 may be used to ensure that the designs are functionally equivalent, and to specify any differences between the designs that are expected.

STA is a timing analysis technique that may be used to ensure that the circuit meets the timing requirements as specified by the design. The STA constraints in LEC/STA constraints 116 may be used to analyze a delay of the different paths in the circuit to ensure that the setup and hold times of the registers are met, and that the circuit is within a desired range. The STA constraints may be used to specify the timing requirements of the circuit, such as the clock period, the setup and the hold times, and a maximum delay that is allowed on each path.

In an example operation, the regular DFT-GLS post-scan 118 may run one or more DFT test patterns to ensure that the final implementation of the design meets the design requirements and is reliable. The DFT post-scan of the regular DFT-GLS post-scan 118 may be used to verify the functionality and testability of the design, while the GLS post-scan can be used to verify the correctness of the synthesized netlist. For example, the regular DFT-GLS post-scan 118 may run stuck-at-scan and/or transition scan on the circuit at the scan stitching design stage 110. In this example, the stitched scan chain at the scan stitching design stage 110 may be utilized to capture data output and compare the captured data output with an expected data output. The comparison may be used to verify the functionality and testability of the design, and the correctness of the synthesized netlist.

At the DFT-GLS design stage 104 of the DFT process 100, the DFT test patterns such as ATPG, EDT, and LBIST test patterns from the spatial aware DFT-GLS post-PD scan 102 may be applied to the targeted portions to improve the yield while generating test vectors with least to no impact to test time. The spatial aware DFT-GLS post-PD scan 102 may include hardware, software, or a combination thereof, that can generate the DFT test patterns and apply the generated DFT test patterns to the targeted portions to verify its functionality and design testability.

In some embodiments, the spatial aware DFT-GLS post-PD scan 102 may use a preconfigured policy (not shown) to define thresholds or conditions for creating the targeted portions, define parameters for clock gating of the targeted portions, and/or limit/manage the data path gating of flops in each of the targeted portions. The preconfigured policy may include user-entered instructions for implementing the spatially aware DFT as described herein.

For example, and based upon the preconfigured policy, a physical layout of the CUT is divided into different portions (or grids) where each of the portions is associated with a set (respective set) of components. With the divided physical layout of the CUT, the preconfigured policy may also define conditions or thresholds for creating the targeted portions from the divided layout. For example, a threshold for creating the targeted portions may include a maximum of four portions for each targeted portion. In another example, a condition for creating the targeted portions may include adjacent portions only. In another example, the targeted portions are classified or grouped based on the associated cell density, associated IR voltage drop, or any other user-entered classifications or conditions for creating the targeted portions. In these examples, the preconfigured policy may further define the toggling of the signal clocks during sequential application of the DFT test patterns or scanning of the targeted portions. In this regard, the use of clock gating on the targeted portions during the testing mode may reduce simultaneous toggling of physically proximate or adjacent high-speed circuits. In some embodiments, the data path gating may be implemented at each of the targeted portions to further reduce capture power of data output.

FIG. 2 illustrates an example spatial aware DFT-GLS post-PD scan 202 that can be used to verify the functionality and testability of the design of a CUT 203. CUT 203 may include components 201-1 to 201-N (or components 201) that can be non-uniformly located at different locations on the CUT 203. Components 201 may include logic circuits, memory cells (e.g., memory components), or a combination thereof. As shown, the spatial aware DFT-GLS post-PD scan 202 may include a preconfigured policy 205 that further includes a targeted portions creation 207, clock gating instruction 209, clock gating instruction 211, and testing instruction 213. Without limitation, preconfigured policy 205 may include user-entered instructions that can define the conditions or thresholds for creating the targeted portions, identify components 201 that are included in each of the targeted portions, clock gating of the targeted portions, and implementation of the data path gating of flops (not shown) in each of the targeted portions.

Targeted portions creation 207 may include user-entered instructions for creating the targeted partitions. The user-entered instructions may include conditions, thresholds, or classifications for grouping of the grids on the CUT 203 to form the targeted portions. For example, the user-entered instructions may include the use of a fixed grid method, cell density method, or IR voltage drop method to divide a physical layout of the CUT 203 into multiple grids or portions. In this example, the user-entered instructions may further include additional conditions, thresholds, or classifications to create the targeted portions from the divided physical layout. For example, the plurality of targeted portions (not shown) may correspond to different cell densities on the CUT 203. In another example, the targeted portions may correspond to different IR voltage drops (or hotsports). In another example, the targeted portions are classified based on the physical location of the components 201 on the CUT 203, and so on. In these examples, the targeted portions are created based upon the conditions, thresholds, or classifications as may be defined by user-entered instructions that can be stored in the targeted portions creation 207.

Clock gating instruction 209 may include user-entered instructions for association or coupling of a clock signal to each of the targeted portions. The associated clock signal may facilitate individual, parallel scanning of two or more targeted portions, or simultaneous scanning of all targeted portions as may be defined by the testing instruction 213. In some embodiments, the clock gating instruction 209 may define various levels of granularity, ranging from gating the entire clock domain to selectively gating clock signals within a specific targeted portion or portions.

Data path gating instruction 211 may include user-entered instructions for associating a gating logic to each flop in the targeted portions to enable or disable the flow of data through specific paths during test mode. In some embodiments, each gating logic that is associated to each flop in the targeted portions may use an LPE signal to enable or disable the flow of data through specific paths during the test mode. In these embodiments, the LPE signal may facilitate reduction of capture power during the test mode.

Testing instruction 213 may include user-entered instructions that define the sequence, conditions, or thresholds for an application of the DFT test patterns to the targeted portions. For example, the user entered instructions may prioritize the application of the DFT test patterns to portions of the CUT 203 that are associated with high cell density. In another example, the user entered instructions may define the sequence of toggling of the clock signals during targeted application of the DFT test patterns to the targeted portions based on power thresholds. In another example, the user entered instructions may define the particular type of DFT test pattern to be applied to each of the targeted portions. In another example, the user entered instructions may define the timing and sequence of enabling of disabling the LPE signals for data path gating, and so on.

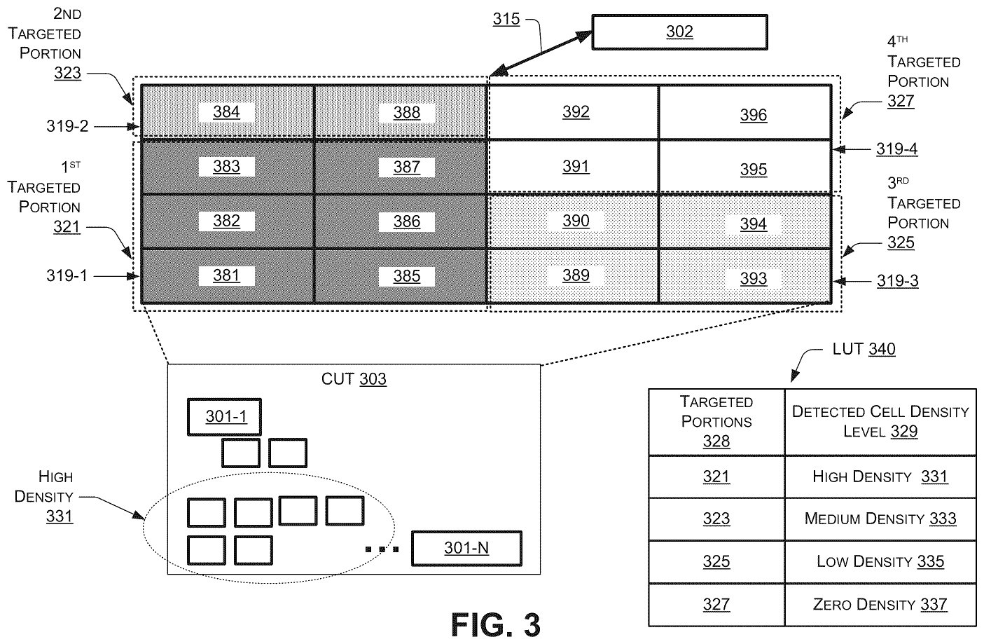

As further described in FIGS. 3-5 below, the generated DFT test patterns 215 may be selectively applied to the targeted portions that may be created using the fixed grid method, cell density method, IR voltage drop method, and additional conditions or thresholds as may be defined by the preconfigured policy.

FIG. 3 is an example division of the physical layout of a CUT 303 and subsequent creation of the targeted portions for a selective application of DFT test pattern 315 from spatial aware DFT-GLS post-PD scan 302. The CUT 303 may include components 301-1 to 301-N that can be non-uniformly located at different areas on the CUT 303. In this regard, different levels of cell density may be distributed across the CUT 303. For illustration purposes, the example CUT 303 may include a compact location of substantially similar levels or range of cell densities; however, similar levels or range of cell densities can be found in scattered locations on the CUT 303.

In some embodiments, and as may be defined by the preconfigured policy (not shown), the physical layout of the CUT 303 may be first divided into portions 381-396 based upon the cell density grid method. The portions 381-396 may include similar sizes and shapes, and each of the portions 381-396 may be associated with corresponding level of cell density. With the divided layout, the preconfigured policy may further define conditions or thresholds for grouping of the portions 381-396 to create the targeted portions. These conditions or thresholds may include the total number of desired targeted portions for the CUT 303, level or range of cell density for each targeted portion, threshold number of portions to be included for each targeted portion, physical locations of the portions whether adjacent or non-adjacent to one another, type of circuit components whether high-speed or high-impedance, and the like.

For example, and as may be defined by the preconfigured policy, the condition or threshold for creating the targeted portions includes a particular range of cell density and a limit to number of portions for each targeted portion. In this example, a first targeted portion 321 may be created from the group of portions 381, 382, 383, 385, 386, and 387; a second targeted portion 323 may be created from the portions 384, and 388; a third targeted portion 325 may be created from the portions 389, 390, 393, and 394; and a fourth targeted portion 327 may be created from the portions 391, 392, 395, and 396. Each of these created targeted portions satisfy the additional condition or threshold as may be defined by the preconfigured policy. As shown, each of the first targeted portion 321, second targeted portion 323, third targeted portion 325, and the fourth targeted portion 327 may be associated with clock signals 319-1, 319-2, 319-3, and 319-4, respectively.

Following the example above, the grouped portions to create the corresponding targeted portion are for illustration purposes only. The grouped portions need not be in a compact location if the conditions or thresholds imposed by the preconfigured policy are satisfied. For example, the first targeted portion 321 is created from the group of portions 381, 382, 383, 385, 386, and 387, which are in a compact location but are within a threshold level or range of cell density. However, the first targeted portion 321 may also be created from scattered portions (not shown) if the scattered portions satisfy the threshold level or range of cell density.

In some embodiments, the preconfigured policy may use a look-up table (LUT) 340 to store a targeted portions 328 and corresponding detected cell density level 329. The targeted portions 328 may include the created targeted portions while the detected cell density level 329 may include different levels of cell density as may be defined by the preconfigured policy. For example, the first targeted portion 321 is identified to be associated with a high density 331; second targeted portion 323 is identified to be associated with a medium density 333; third targeted portion 325 is identified to be associated with a low density 335; and the fourth targeted portion 327 is identified to be associated with a zero density 337. The high density 331 may indicate a high volume of components within the area that is covered by the portions 381, 382, 383, 385, 386, and 387 of the first targeted portion 321. The high density 331 is illustrated in FIG. 3 to include a dark filling.

In some embodiments, the preconfigured policy may define the toggling of the created targeted portions for purposes of applying the DFT test pattern 315. In one example, the toggling may prioritize the application of the DFT test patterns 315 to the first targeted portion 321 (or portions 381, 382, 385, and 366) that is associated with the high density 331. The high density 331 may indicate the high volume or number of components within the area that is covered by the physical layout of the first targeted portion 321. In this example, the clock signal 319-1 for the first targeted portion 321 is enabled while the clock signals 319-2, 319-3, and 319-4 are disabled during the scanning of the first targeted portion 321. In another example, and at a next time instant, the toggling may include the application of the DFT test patterns to the second targeted portion 323 (or portions 384, 386) that is associated with the medium density 333. In this example, the clock signal 319-2 for the second targeted portion 323 is enabled while the clock signals 319-1, 319-3, and 319-4 are disabled during the testing operation.

In another example, and at a next time instant, the toggling may include the parallel application of the DFT test patterns to the first targeted portion 321 and the second targeted portion 323. In this example, the clock signals 319-1 and 319-2 for the first targeted portion 321 and the second targeted portion 323, respectively, may be enabled while the clock signals 319-3, and 319-4 are disabled during the testing operation, and so on. In these examples, the preconfigured policy may define the sequence, timing, or conditions for toggling of the clock signals 319 for selective scanning of the first targeted portion 321, second targeted portion 323, third targeted portion 325, and/or the fourth targeted portion 327.

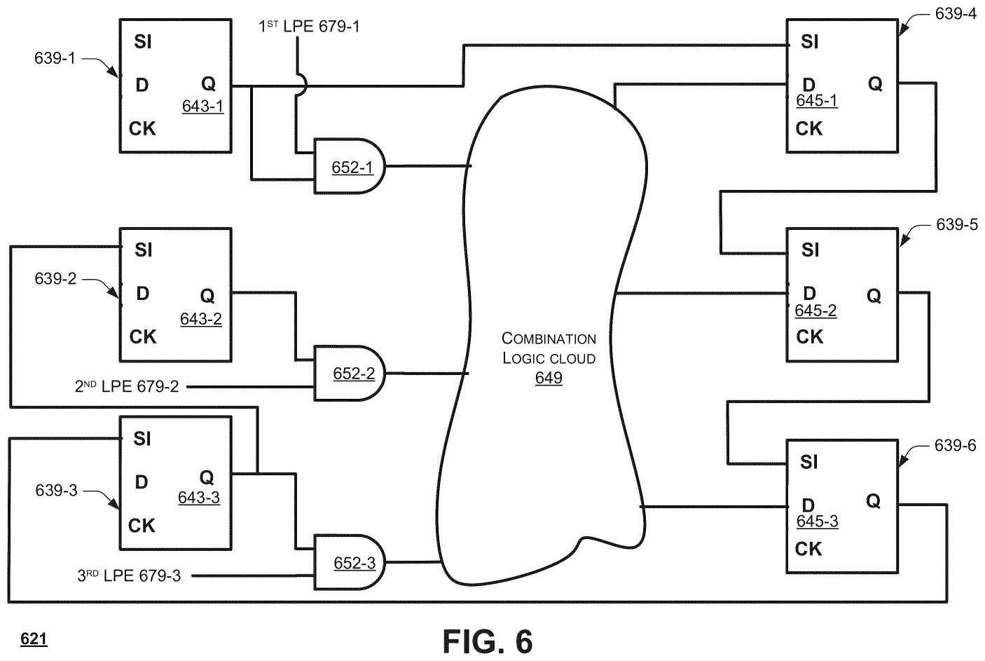

As further described in FIG. 6, the data path gating of flops for each of the first targeted portion 321, second targeted portion 323, third targeted portion 325, and the fourth targeted portion 327 may be implemented to reduce capture power since the flops can be toggled using the gating logic.

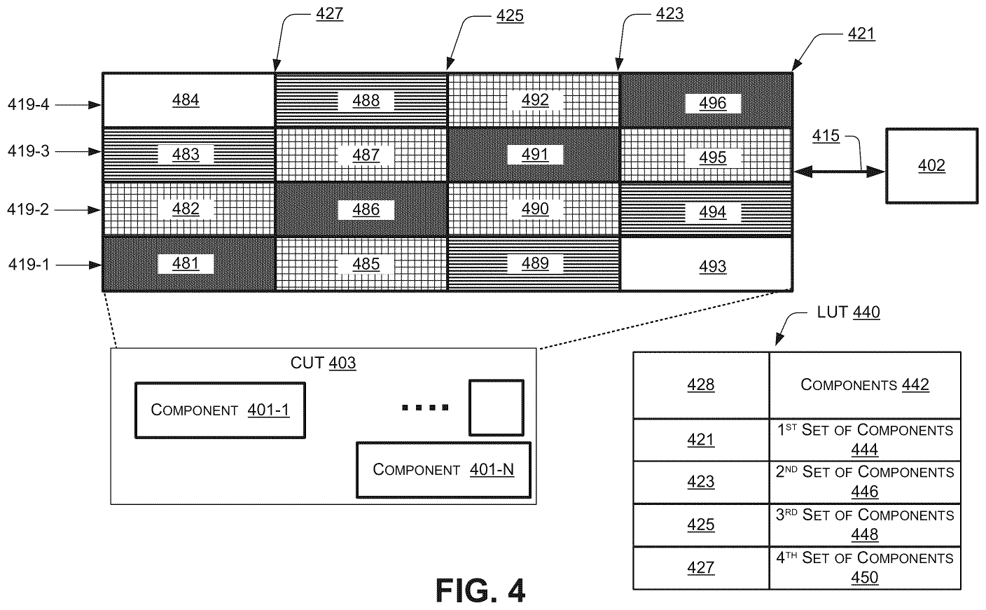

FIG. 4 is an example division of the physical layout of a CUT 403 and subsequent creation of the targeted portions for a selective application of a DFT test pattern 415 from a spatial aware DFT-GLS post-PD scan 402. The CUT 403 may include components 401-1 to 401-N that can be non-uniformly located at different areas on the CUT 403. In some embodiments, and as may be defined by the preconfigured policy (not shown), the physical layout of the CUT 403 may be first divided into portions 481-496 based upon the fixed grid method. With the divided layout, the preconfigured policy may further define conditions or thresholds for grouping of the portions 481-496 to create the targeted portions. These conditions or thresholds may include the total number of desired targeted portions for the CUT 403, threshold number of portions to be included for each targeted portion, physical locations of the portions whether adjacent or non-adjacent to one another, or any other configuration or designation as may be defined by the preconfigured policy.

For example, and as may be defined by the preconfigured policy, the condition or threshold for creating the targeted portions includes a limit to number of portions for each targeted portion and that the portions are non-adjacent to one another. In this example, a first targeted portion 421 may be created from the group of portions 481, 486, 491, and 496; a second targeted portion 423 may be created from the portions 482, 487, 492, 485, 490, and 495; a third targeted portion 425 may be created from the portions 483, 488, 489, and 494; and a fourth targeted portion 427 may be created from the portions 484, and 493. Each of these created targeted portions satisfy the additional condition or threshold as may be defined by the preconfigured policy. As shown, each of the first targeted portion 321, second targeted portion 323, third targeted portion 325, and the fourth targeted portion 327 may be associated with clock signals 319-1, 319-2, 319-3, and 319-4, respectively.

In some embodiments, the preconfigured policy may use a look-up table (LUT) 440 to store a divided layout 428 and corresponding components 442. For example, the first targeted portion 421, second targeted portion 423, third targeted portion 425, and the fourth targeted portion 427 may be associated with a first set of components 444, second set of components 446, third set of components 448, and fourth set of components 450, respectively. In this example, the preconfigured policy may use the LUT 440 to identify the components that may be associated with each of the targeted portions.

In some embodiments, the preconfigured policy may define the toggling of the clock signals 419 that are associated with the created targeted portions for purposes of applying the DFT test pattern 415. In one example, the toggling may prioritize the application of the DFT test pattern 415 to the first targeted portion 421. In this example, the clock signal 419-1 for the first targeted portion 321 is enabled while the clock signals 419-2, 419-3, and 419-4 are disabled during the testing operation. In another example, and a next time instant, the toggling may include the parallel application of the DFT test pattern 415 to the third targeted portion 425 and the fourth targeted portion 427. In this example, the clock signals 419-3 and 419-4 for the third targeted portion 425 and the fourth targeted portion 427, respectively, may be enabled while the clock signals 419-1, and 419-2 are disabled during the testing operation, and so on. In these examples, the preconfigured policy may define the sequence, timing, or conditions for toggling of the clock signals 419 for selective scanning of the first targeted portion 421, second targeted portion 423, third targeted portion 425, and/or the fourth targeted portion 427.

As further described in FIG. 6, the data path gating of flops for each of the first targeted portion 421, second targeted portion 423, third targeted portion 425, and the fourth targeted portion 427 may be implemented to reduce capture power since the flops can be toggled using the gating logic.

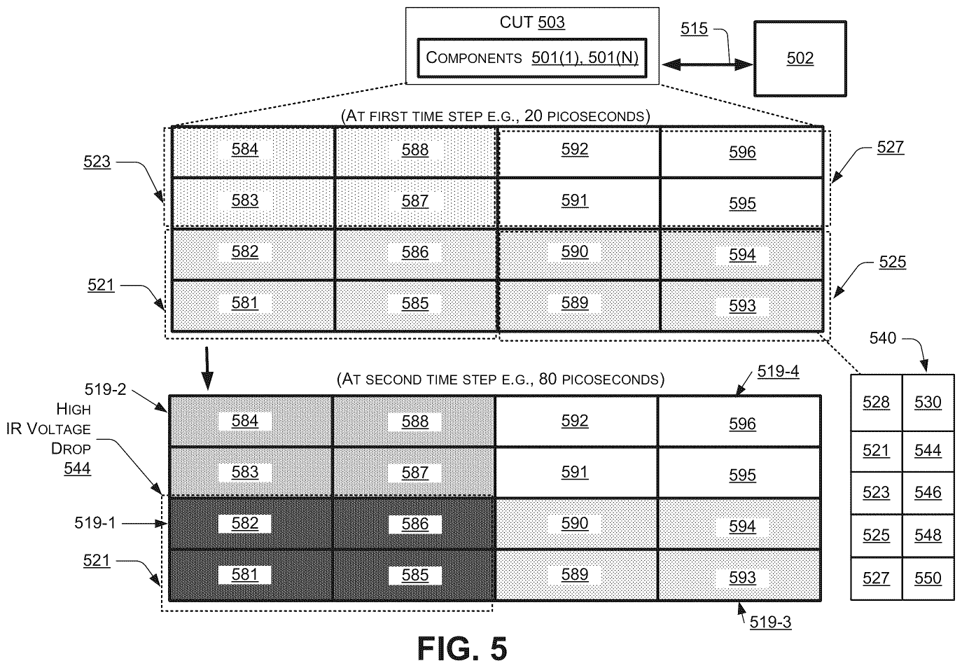

FIG. 5 is an example division of the physical layout of a CUT 503 and subsequent creation of the targeted portions for a selective application of a DFT test pattern 515 from a spatial aware DFT-GLS post-PD scan 502. The CUT 503 may include components 501-1 to 501-N that can be non-uniformly located at different areas on the CUT 503. For illustration purposes, the example CUT 503 may include a compact location of substantially similar levels or range of IR voltage drop; however, similar levels or range of IR voltage drop can be found in scattered locations on the CUT 503.

In some embodiments, and as may be defined by the preconfigured policy (not shown), the physical layout of the CUT 503 may be first divided into portions 581-596 based upon the IR voltage drop method. The portions 581-596 may include similar sizes and shapes, and each of the portions 581-596 may be associated with corresponding level of IR voltage drop. With the divided layout, the preconfigured policy may further define conditions or thresholds for grouping of the portions 581-596 to create the targeted portions. These conditions or thresholds may include the total number of desired targeted portions for the CUT 503, level or range of IR voltage drop for each targeted portion, threshold number of portions to be included for each targeted portion, physical locations of the portions whether adjacent or non-adjacent to one another, and the like.

For example, and as may be defined by the preconfigured policy, the condition or threshold for creating the targeted portions includes a particular range of IR voltage drop and a limit to number of portions for each targeted portion. In this example, a first targeted portion 521 may be created from the group of portions 581, 582, 585, and 586; a second targeted portion 523 may be created from the group of portions 583, 584, 587, and 588; a third targeted portion 525 may be created from the group of portions 589, 590, 593, and 594; and a fourth targeted portion 527 may be created from the group of portions 591, 592, 595, and 596. Each of these created targeted portions satisfy the additional condition or threshold as may be defined by the preconfigured policy. As shown, each of the first targeted portion 521, second targeted portion 523, third targeted portion 525, and the fourth targeted portion 527 may be associated with clock signals 519-1, 519-2, 519-3, and 519-4, respectively.

Following the example above, the grouped portions to create the corresponding targeted portion are for illustration purposes only. The grouped portions need not be in a compact location if the conditions or thresholds imposed by the preconfigured policy are satisfied. For example, the first targeted portion 521 is created from the group of portions 581, 582, 585, and 586, which are in a compact location but are within a threshold level or range of IR voltage drop. However, the first targeted portion 521 may also be created from scattered portions (not shown) if the scattered portions satisfy the threshold level or range of IR voltage drop.

In some embodiments, the preconfigured policy may use a look-up table (LUT) 540 to store a targeted portions 528 and corresponding detected IR voltage drop level 530. The targeted portions 528 may include the created targeted portions while the detected IR voltage drop level 530 may include different levels of IR voltage drop (or hotspot) as may be defined by the preconfigured policy. For example, the first targeted portion 521, second targeted portion 523, third targeted portion 525, and the fourth targeted portion 527 may be associated with a high IR voltage drop 544, medium IR voltage drop 546, low IR voltage drop 548, and no IR voltage drop 550, respectively. In this example, the preconfigured policy may use the LUT 540 to identify the IR voltage drop levels that may be associated with each of the targeted portions. In this example, the IR voltage drop levels may include the measured IR voltage drop after a lapse of a particular time period. For example, the detected IR voltage drop level 530 is taken at the end of 80 picoseconds as shown.

In some embodiments, the preconfigured policy may define the toggling of the created targeted portions for purposes of applying the DFT test pattern 515. In one example, the toggling may prioritize the application of the DFT test pattern 515 to the first targeted portion 521 (or portions 581, 582, 585, and 586) that is associated with a high IR voltage drop 544. In this example, the clock signal 519-1 for the first targeted portion 521 is enabled while the clock signals 519-2, 519-3, and 519-4 are disabled during the testing operation. In another example, and a next time instant, the toggling may include the application of the DFT test pattern 515 to the second targeted portion 523. In this example, the clock signal 519-2 for the second targeted portion 523 may be enabled while the clock signals 519-1, 519-3, and 519-4 are disabled during the testing operation, and so on. In these examples, the preconfigured policy may define the sequence, timing, or toggling of the clock signals 519 for selective scanning of the first targeted portion 521, second targeted portion 523, third targeted portion 525, and/or the fourth targeted portion 527.

As further described in FIG. 6, the data path gating of flops for each of the first targeted portion 521, second targeted portion 523, third targeted portion 525, and the fourth targeted portion 527 may be implemented to reduce capture power since the flops can be toggled using the gating logic.

FIG. 6 is an example data path gating on a targeted portion 621 in accordance with a number of embodiments of the present disclosure. The data path gating may be based on a preconfigured policy as described herein. For illustration purposes, the targeted portion 621 may include flops 639-1, 639-2, 639-3, 639-4, 639-5, and 639-6 with corresponding output (Q) pins and data input (D) pins. In some embodiments, the flops 639-1, 639-2, 639-3, 639-4, 639-5, and 639-6 may form a scan chain. Flops 639-1, 639-2, 639-3 may include Q pins 643-1, 643-2, 643-3, respectively, while flops 639-4, 639-5, 639-6 may include D pins 645-1, 645-2, 645-3, respectively. The Q pins 643-1, 643-2, 643-3 may be coupled to the D pins 645-1, 645-2, 645-3 via a combination logic cloud 649, which may include a logic circuitry to implement combination logic, for example.

In some embodiments, as may be defined by the preconfigured policy, the data path gating may utilize AND logic gates 652-1, 652-2, 652-3 to couple the Q pins 643-1, 643-2, 643-3 to the D pins 645-1, 645-2, 645-3, respectively. For example, AND logic gate 652-1 connects the Q pin 643-1 to the D pin 645-1, AND logic gate 652-2 connects the Q pin 643-2 to the D pin 645-2, and AND logic gate 652-3 connects the Q pin 643-3 to the D pin 645-3. In example, a first LPE 679-1, second LPE 679-2, and a third LPE 679-3 may be used to enable or disable the AND logic gates 652-1, 652-2, 652-3, respectively, to implement the data path gating.

For example, the preconfigured policy may define the data path gating to be implemented only during data capture. In this example, the preconfigured policy may use the first LPE 679-1, second LPE 679-2, and/or the third LPE 679-3 to implement the defined coupling between the Q pins 643-1, 643-2, 643-3 and the D pins 645-1, 645-2, 645-3, respectively. The coupling may be sequential or implemented in parallel between two or more Q pins. In this regard, the use of the first LPE 679-1, second LPE 679-2, and/or the third LPE 679-3 may reduce shifting power during data capture.

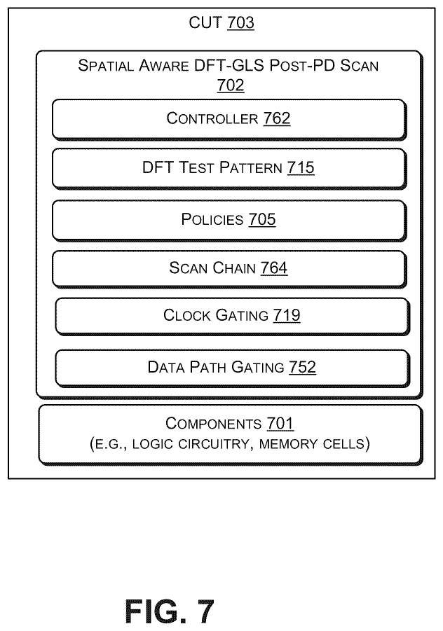

FIG. 7 is an example block diagram of a CUT 703 that implements the spatial aware DFT-GLS post-PD scan 702 on components 701 to test the functionality and testability of the circuit. As shown, the spatial aware DFT-GLS post-PD scan 702 may include a controller 762, DFT test pattern 715, policies 705, scan chain 764, clock gating 719, and data path gating 752. The components 701 are analogous to the components 301, 401, and 501 in FIGS. 3-5, respectively.

Controller 762 may include hardware, software, or a combination thereof, that implements the policies 705 during testing mode. Without limitation, and based on policies 705, controller 762 may create the targeted portions, enable parallel scanning or application of the DFT test pattern 715 to the targeted portions, control the clock gating 719, control the data path gating 752, and the like. Controller 762 may be further configured to set the test mode or functional mode of the CUT 703. Controller 762 may be further configured to implement testing. In some cases, the controller 762 may receive user-entered policy or policy updates to update the policies 705.

DFT test pattern 715 may include ATPG, LBIST, MBIST, and/or EDT test patterns that may be used during the testing mode. ATPG test pattern may include generated test vectors or series of test vectors that may be applied to the components 701. The series of test vectors may execute, for example, the stuck-at-fault, transition fault, and other types of test methods. LBIST and MBIST test patterns may include built-in test patterns to evaluate functionality of logic circuitry and memory cells, respectively, of the components 701. EDT test pattern may include deterministic test patterns that are incorporated into chip's design. The EDT test pattern may include predefined test patterns that can be stored in an Automatic Test Equipment (ATE) and applied to the CUT.

Policies 705 may include user-entered instructions for creating the targeted portions, sequence of scanning the targeted portions via clock gating, enabling or disabling data pathways via data path gating, and the like. For example, a user-entered instruction may include the use of a fixed grid method to divide a physical layout of the CUT 703. The user-entered instruction may also include additional condition such as a threshold number of grids to create the targeted portions. In another example, the user-entered instruction may also include association of a clock signal to each of the targeted portions, limit the number of parallel scanning of the targeted portions, enable data pathways during capture, and the like. In these examples, the controller 762 may receive and implement the user-entered instructions during testing mode.

Scan chain 764 may include flops that are inserted into the gate-level netlist that are generated by the synthesis stage in the DFT process. The scan chain 764 may facilitate the testing by providing a way to load and unload the DFT test pattern 715 into the components 701. For example, the DFT test pattern 715 may be loaded to flip-flops in the circuit that are grouped as a scan chain. The flip-flops are then reconnected in a specific order to form the scan chain 764. The controller 762 may generate the necessary control logic to drive the scan chain during testing.

Clock gating 719 may include hardware, software, or a combination thereof, that is configured to provide toggling of the targeted portions during testing. For example, a first targeted portion is enabled for testing while the rest of the targeted portions are disconnected by disabling their respective clocks. In this example, the clock gating 719 may be configured to support the enabling or disabling of the clock signals that are associated with the targeted portions.

Data path gating 752 may include hardware, software, or a combination thereof, that is configured to provide toggling of data pathways during data capture. In some embodiments, an LPE signal for each data pathway in a targeted portion may be used to toggle a connection between flops.

Components 701 may include logic circuitry, memory cells, and bus interfaces that implement the functionality of the CUT 703. In some embodiments, the LBIST test patterns may be used to test the logic circuitry while the MBIST test patterns may be used to test the memory cells. In other embodiments, the ATPG test patterns and the EDT test patterns may be used to test the components 701.

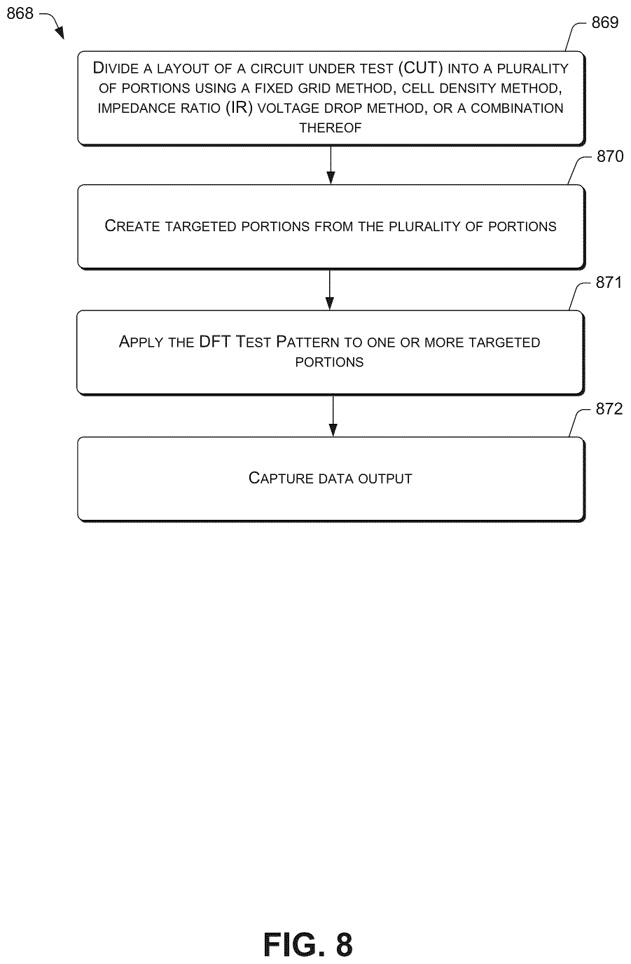

FIG. 8 is a flow diagram of method 868 for implementing targeted spatial aware DFT-GLS post-PD scanning or testing to verify functionality and testability of a CUT in accordance with a number of embodiments of the present disclosure. The methods described herein can be performed by hardware (e.g., a processing device, circuitry, dedicated logic, programmable logic, microcode, hardware of a device, integrated circuit, etc.). With respect to FIG. 7, for example, the method can be performed by circuitry associated with a spatial aware DFT-GLS post-PD scan, such as the spatial aware DFT-GLS post-PD scan 702 illustrated in FIG. 7. Although shown in a particular sequence or order, unless otherwise specified, the order of the processes with respect to any of the method flow diagrams described herein can be modified. Thus, the illustrated embodiments should be understood only as examples, and the illustrated processes can be performed in a different order, and some processes can be performed in parallel.

At 869, the method can include dividing, by a controller, a physical layout of a CUT into a plurality of portions using a fixed grid method, cell density method, IR voltage drop method, or a combination thereof. The spatial aware DFT-GLS post-PD scan may use the preconfigured policy to select the method for dividing the physical layout of the CUT.

At 870, the method can include creating, by the controller, targeted portions from the plurality of portions. In some embodiments, the policy may include additional user-entered conditions, thresholds, and/or other parameters for selecting or grouping the portions into targeted portions. For example, the policy may limit grouping of the divided portions to a maximum of six adjacent or non-adjacent portions. In this example, each of the created targeted portions may not exceed this condition. In another example, the policy may classify the grouping of the divided portions to different levels based on their corresponding IR voltage drops. In this example, each of the created targeted portions may correspond to a group of portions that is associated with a particular level of IR voltage drop.

In some embodiments, the policy may include the clock gating of each of the targeted portions. In these embodiments, each of the targeted portions may be associated with corresponding clock signals. In this manner and based upon the sequence of scanning the targeted portions, one or more clock signals may be enabled simultaneously while the rest of the clock signals are disabled.

At 871, the method can include applying, by the controller, DFT test pattern to one or more targeted portions. The DFT test patterns may include, without limitation, ATPG, LBIST, MBIST, and EDT test patterns.

At 872, the method can include capturing, by the controller, data output to verify functionality and testability of the CUT. In some embodiments, the policy may include data path gating of the flops in each of the targeted portions. Here, the policy may define the sequence of the data path gating via the use of the LPEs to reduce power during capturing of data output.

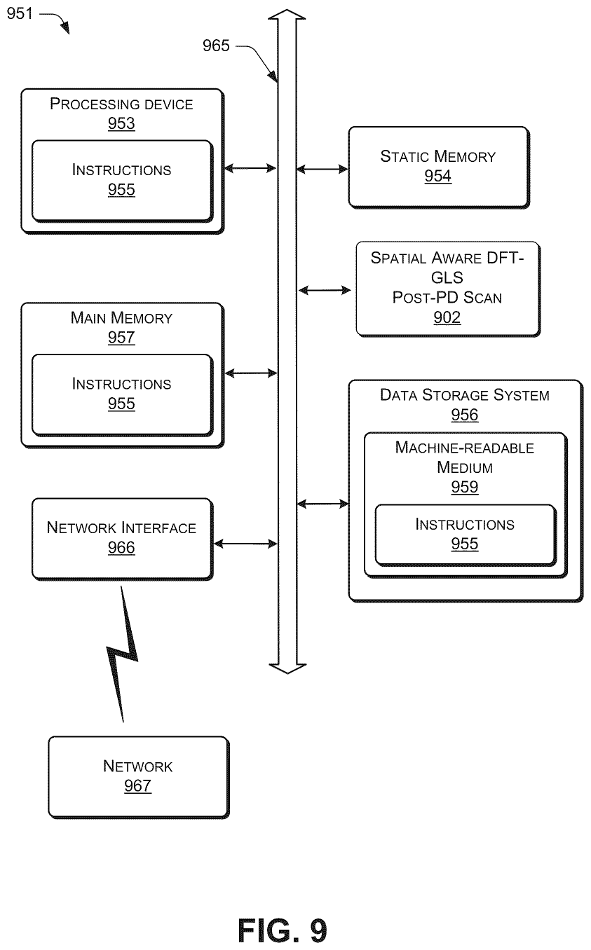

FIG. 9 illustrates an example computer system 951 within which a set of instructions 955, for causing the machine to perform various methodologies discussed herein, can be executed. In various embodiments, the computer system 951 can correspond to a system (e.g., the DFT-GLS post-PD scan as described with respect to FIG. 7). In alternative embodiments, the machine can be connected (e.g., networked) to other machines in a local area network (LAN), an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 951 includes a spatial aware DFT-GLS post-PD scan 902, processing device 953, a static memory 954 (e.g., flash memory, a main memory 957, static random access memory (SRAM), etc.), and a data storage system 956, which communicate with each other via a bus 965. The spatial aware DFT-GLS post-PD scan 902 is analogous to the spatial aware DFT-GLS post-PD scan 102, 202, 702 of FIGS. 1, 2, and 7, respectively.

The processing device 953 represents one or more general-purpose processing devices such as a microprocessor, a CPU, a GPU, or the like. More particularly, the processing device can be a CISC microprocessor, RISC microprocessor, VLIW microprocessor, or a processor implementing other instruction sets, or processors implementing a combination of instruction sets. The processing device 953 can also be one or more special-purpose processing devices such as an ASIC, an FPGA, a DSP, network processor, or the like. The processing device 953 is configured to execute instructions 955 for performing the operations and steps discussed herein. The computer system 951 can further include a network interface device 966 to communicate over the network 967.

The data storage system 956 can include a machine-readable storage medium 959 (also known as a computer-readable medium) on which is stored one or more sets of instructions 955 or software embodying any one or more of the methodologies or functions described herein. The instructions 955 can also reside, completely or at least partially, within the main memory 957 and/or within the processing device 953 during execution thereof by the computer system 951, the main memory 957 and the processing device 953 also constituting machine-readable storage media.

In some embodiments, the main memory 957 may be implemented using computer-readable media. Computer-readable media includes, at least, two types of computer-readable media, namely computer-readable storage media and communications media. Computer-readable storage media includes, but is not limited to, Random Access Memory (RAM), Dynamic Random Access Memory (DRAM), Read-Only Memory (ROM), Electrically Erasable Programmable Read-Only Memory (EEPROM), flash memory or other memory technology, Compact Disc-Read-Only Memory (CD-ROM), digital versatile disks (DVD), high-definition multimedia/data storage disks, or other optical storage, magnetic cassettes, magnetic tape, magnetic disk storage or other magnetic storage devices, or any other non-transmission medium that can be used to store information for access by a computing device. As defined herein, computer-readable storage media do not consist of and are not formed exclusively by, modulated data signals, such as a carrier wave. In contrast, communication media may embody computer-readable instructions, data structures, program modules, or other data in a modulated data signal, such as a carrier wave, or other transmission mechanisms.

The instructions 955 can be executed to carry out any of the embodiments described herein. For example, the instructions 955 can be executed to implement preconfigure policy such as the policies 705 in FIG. 7.

While the machine-readable storage medium 959 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combinations of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method, comprising:
dividing a layout of a circuit under test (CUT) into a plurality of grids based on a preconfigured policy;
creating, based on the preconfigured policy, a plurality of targeted portions from the divided layout of the CUT;
applying a Design for Testability (DFT) test pattern to the plurality of targeted portions; and
capturing data output from the plurality of targeted portions.

2. The method of claim 1, wherein the dividing the layout of the CUT based on the preconfigured policy includes dividing the CUT using a fixed grid method.

3. The method of claim 2, wherein the preconfigured policy further includes a threshold for creating the plurality of targeted portions.

4. The method of claim 1, wherein the preconfigured policy defines a sequence of applying the DFT test pattern to different targeted portions.

5. The method of claim 4, wherein the preconfigured policy includes user-entered instruction for clock gating of the targeted portions to implement the sequence of applying the DFT test pattern to different target portions.

6. The method of claim 1, wherein the preconfigured policy includes user-entered instruction for implementing data path gating of flops when capturing data output from the plurality of targeted portions.

7. The method of claim 1, wherein the dividing the layout of the CUT based on the preconfigured policy includes dividing the CUT using a cell density method.

8. The method of claim 1, wherein the DFT test pattern includes an Automatic Test Pattern Generation (ATPG) test pattern.

9. The method of claim 1, wherein the DFT test pattern includes a Memory Built-In Self Test (MBIST) test pattern.

10. An apparatus, comprising:
a circuit under test (CUT); and
a controller configured to:
divide a layout of the CUT into a plurality of grids based on a preconfigured policy;
create, based on the preconfigured policy, a plurality of targeted portions from the divided layout;
apply a Design for Testability (DFT) test pattern to the plurality of targeted portions; and
capture data output from the plurality of targeted portions.

11. The apparatus of claim 10, wherein the layout of the CUT is logically divided into different sets of grids using a fix grid method associated with the CUT, a relative density of a sets of components in the CUT, a relative voltage drop associated with the sets of components of the CUT, or any combination thereof.

12. The apparatus of claim 10, wherein the controller is further configured to:
toggle, based on the preconfigured policy, clock signals of corresponding targeted portions to apply the DFT test pattern during a testing mode.

13. The apparatus of claim 12, wherein the controller is further configured to implement, based on the preconfigured policy, parallel scanning of two or more targeted portions.

14. The apparatus of claim 10, wherein the controller is further configured to:
group the plurality of grids based on associated voltage drop levels; and
create the targeted portions based on the voltage drop levels that are associated with the group of grids.

15. The apparatus of claim 14, wherein the controller is further configured to:
identify a relatively high voltage hotspot in one of the targeted portions; and
apply the DFT test pattern to the one of the targeted portions that is associated with the identified high voltage hotspot.

16. The apparatus of claim 10, wherein the controller is further configured to:
implement, based on the preconfigured policy, data path gating of flops on each of the targeted portions.

17. The apparatus of claim 16, wherein the data path gating utilizes a gating logic for each flop in each of the targeted regions.

18. A non-transitory computer-readable storage medium comprising instructions that, when executed by a processing device, cause the processing device to:
divide a layout of a circuit under test (CUT) into a grid based on a preconfigured policy, wherein the layout of the CUT is logically divided into different portions using a fix grid method, cell density method, a relative voltage drop method, or any combination thereof;
create, based on the preconfigured policy, a plurality of targeted portions from the divided layout of the CUT;
apply a Design for Testability (DFT) test pattern to each of the plurality of targeted portions, wherein application of the DFT test pattern is facilitated by corresponding clock signals of each of the targeted portions; and
capture data output from the plurality of targeted portions.

19. The medium of claim 18, wherein the preconfigured policy includes a user-entered instruction for a sequence of applying the DFT test pattern to each of the plurality of targeted portions.

20. The medium of claim 18, wherein the preconfigured policy includes a user-entered instruction for implementing a data path gating of each flop in the plurality of targeted portions.
